(19) United States
(12) Patent Application Publication
(10) Pub. No.: US 2024/0180026 A1
(43) Pub. Date: May 30, 2024

(54) PRINTABLE COMPOSITION FOR OPTO-ELECTRONIC DEVICE

(71) Applicant: PEROVSKIA SOLAR AG, Aubonne (CH)

(72) Inventors: Anand VERMA, Aubonne (CH); Tobias MEYER, Fechy (CH)

(21) Appl. No.: 18/285,412

(22) PCT Filed: Apr. 4, 2021
(86) PCT No.: PCT/IB2021/052871

§ 371 Date: Oct. 3, 2023

(51) Int. Cl. H10K 85/50; H10K 30/15; H10K 30/40; H10K 30/81; H10K 71/13; H10K 71/40; H10K 71/60

(52) U.S. Cl. CPC H10K 85/50; H10K 30/15; H10K 30/40; H10K 30/81; H10K 71/135; H10K 71/40; H10K 71/611

(57) ABSTRACT

The invention concerns a perovskite composition for a functional layer of an optoelectronic device, comprising an organic precursor of a metal-halide perovskite, an inorganic material, a matrix polymer, and at least one organic solvent. The invention also concerns an optoelectronic device, in which all functional layers may be inkjet-printed, and a method for producing the device.

### TECHNICAL DOMAIN

The present invention concerns perovskite optoelectronic devices and compositions as well as methods for producing such devices.

### RELATED ART

Based on their outstanding efficiency in converting solar energy perovskite solar cells (PSC) have demonstrated a great potential as attractive renewable energy source over the past decade. The success story of PSCs began only on 2009 with the work of Miyasaka and co-workers used perovskite nanocrystals as sensitizers in a photovoltaic cell architecture known as dye-sensitized solar cells (Kojima A, et al; J. Am. Chem. Soc. 2009; 131, p. 6050-6051). It was demonstrated that perovskite crystals can act as light absorbing material and as electron- and hole-transporting layers in form of mesoscopic networks as well as in form of solid polycrystalline layers. Since then, several studies have confirmed the impressive performance of PSCs with reported power conversions of over 25% of solar energy.

Currently, state of the art perovskite solar cells encompass a variety of different materials and configurations, ranging from all organic to all inorganic contacts, with or without a mesoporous scaffold. Similarly, various deposition methods for the perovskite material, such as single-step, sequential, or dual-source sublimation, as well as solution and sublimation processes are being investigated.

Carbon-based monolithic PSC are particularly suited to large scale production. Today a series of fabrication methods for these cells, including wet coating, such as spin coating, screen printing, spray coating, slot die coating, as well as evaporation techniques, such as thermal evaporation, have been applied. Individual layers of carbon-based PSC have also been fabricated by printing or coating.

Today, fabrication methods of these layered carbon-based PSC are subject to continuous development and have given rise to several approaches in recent years, such as those described in the documents listed below.

WO2019/219951 A1 describes a method of producing layers on an electronic device by co-firing a plurality of different overlapping or superposed films comprising metal oxides, and/or carbon in addition to organic components.

WO2019/219952 A1 discloses a slot-die deposition method for layers of an electronic device. The layers comprise compact inorganic layers, mesoporous inorganic layers, a carbon layer and a layer comprising organic-inorganic perovskite.

WO2020/147940 A1 discloses a composition comprising TiO2 particles, which may be a mesoporous anastase and, optionally, further TiO2 precursors. The document furthermore discloses a method of inkjet printing the TiO2 composition on a substrate.

Despite these different approaches to improve the fabrication methods of carbon-based perovskite optoelectronic devices, the manufacturing processes described in the state of the art and currently used are still quite time-consuming and uneconomical in terms of energy consumption.

In addition, the production methods known in the art provide no satisfactory solution for a rapid, precise and cost-efficient fabrication of robust mesoporous perovskite optoelectronic devices with customizable dimension, such as Internet of Things (IoT) devices, or wearable accessories, for example in watches.

The present invention sets out to overcome these deficiencies.

### SHORT DISCLOSURE OF THE INVENTION

An aim of the present invention is the provision of a mesoporous perovskite optoelectronic device which is which can be produced at low energy expenditure and which is robust and durable. The optoelectronic device should furthermore be capable of being manufactured in a cost- and time-efficient manner.

It is a further aim of the invention to provide a method for producing a mesoporous optoelectronic device, such as a solar cell, which is fast and versatile.

On the one hand, the fabrication method should be sufficiently fast to be suited for the fabrication of devices with large surface areas. The fabrication method should however also sufficiently versatile and/or precise in order to be suited for a wide variety of optoelectronic devices, ideally the method should be readily customizable to different shapes and sizes of such devices.

According to the invention, these aims are attained by the object of the attached claims, and especially by the independent claims.

In particular, the aims are achieved, by a perovskite composition for a functional layer of an optoelectronic device, comprising an organic precursor of a metal-halide perovskite, an inorganic material, a matrix polymer material or composite mixtures of matrix materials, and at least one organic solvent. The perovskite composition is suitable for fabricating said functional layer of the optoelectronic device by annealing at temperatures at or below 135 degrees Celsius, or below 115 degrees Celsius, preferably at temperatures ranging from 20 degrees Celsius to 100 degrees Celsius, ideally ranging from 50 degrees Celsius to 80 degrees Celsius, for a period of less than 60 minutes, or of less than 15 minutes, preferably for a period of 8 minutes to 12 minutes

Further advantageous aspects of the invention are disclosed in the dependent claims.

Both, the inorganic material as well as organic precursor, which together form the perovskite crystal, are provided in the same composition and disposed onto the optoelectronic device in a single step. The function of the crystallised perovskite material is to absorb light energy and to act as an electron and/or hole transporting material.

The perovskite composition furthermore comprises matrix polymer and/or matrix polymer mixtures. Suitable matrix polymers of varied chain lengths include for example polystyrene (PS), polyethylene terephthalate (PET), polyolefin (PO), poly(vinyl alcohol) (PVA), or, preferably, poly(methyl methacrylate) (PMMA). The matrix polymer may also be a combination of two or more different matrix polymers. Preferably, said matrix polymer or a combination of matrix polymers is comprised in the perovskite composition ranging from 0.1 wt % to 50 wt %, preferably from 0.1 wt % to 10 wt % and most preferably from 0.1 wt % to 2 wt %.

The function of the matrix polymer is to enhance performance and durability, as well as to stabilize the composition and structure of the optoelectronic device. Remarkably, the matrix polymer forms a protective film around the solid particles and material, including the perovskite crystals, without significantly interfering with electron or hole transport. The matrix polymer if selected with insulating property, it has a passivating and/or encapsulating effect on the material it coats. The polymer therefore provides protection for the components it covers without substantially interfering with their function. As a result, the polymer enhances the durability and robustness of the optoelectronic device without interfering with its performance. Moreover, the polymer or small molecules can be functionalized to enhance charge transport like electron conducting or hole-conducting.

During the fabrication of an optoelectronic device, the disposed layers are annealed. When the disposed perovskite composition is heated as part of this annealing step or when it is left to dry by solvent evaporation, the components of this composition penetrate into the underlying layers. This means that the perovskite material as well as the matrix polymer spreads into the underlying layers. The protective effect of the matrix polymer therefore also extends to the material and particles comprised in these layers.

With respect to what is known in the art, the invention provides the advantage that the claimed perovskite composition enables a deposition of the perovskite precursor material in one step and that the perovskite material is protected from environmental damage, such as moisture damage. As a further advantage, the claimed perovskite composition also protects materials comprised in other functional layers of the optoelectronic device, thus enhancing its robustness and durability.

Surprisingly, it was observed as part of this invention, that moisture damaged devices could be re-generate when the perovskite precursor ink comprised PMMA. This effect could also be observed when a separate PMMA composition was applied on top of the device.

The matrix polymer is therefore not only suited to prevent damage of the functional layers it penetrates but it may also at least partially repair such damages. To this end, it is also conceivable to apply a matrix polymer composition separately from compositions comprising perovskite material or perovskite pre-cursors.

A composition comprising a polymer matrix could for example be applied retrospectively on a finished device. It is also possible to apply a polymer matrix composition in during the fabrication of a mesoporous perovskite device after the perovskite material has been disposed onto the device. If a matrix polymer is disposed as a separate layer, it needs to be applied after the perovskite material has been disposed onto the device means the solvent used for dissolving PMMA in this case must be orthogonal to that of perovskite like ethyl acetate, terpineol, toluene, etc.

Preferably, the organic precursor comprised in the perovskite composition is chosen from a group of suitable organic halides known in the art. The inorganic material preferably chosen from a group of metal-halides. Together the inorganic material and the organic precursor give rise to a metal-halide perovskite crystal of the formula AMX₃, wherein A is an organic cation, M is a metal and X is a halide.

The AMX₃ crystal is formed during drying of the perovskite composition on the optoelectronic device. This can occur as part of a separate drying step in the fabrication of the layered device, or during the annealing step.

In a preferred embodiment, the perovskite composition furthermore comprises conductive particles. The term “conductive particles” as used herein means particles which are suitable to function as electrode material. In the optoelectronic device the conductive particles act as a cathode and/or as a back contact. Such conductive particles may for example be carbon constituents, antimony tin oxide (ATO) constituents, Al-doped ZnO (AZO) constituents, or indium tin oxide (ITO) constituents. However, this invention is not limited to these examples and other conductive particles may be used, when comprised in the perovskite composition, the conductive particles are preferably provided ranging from 0.1 wt % to 50 wt %.

Provision of conductive particles in the perovskite composition provides the advantage that the different functions of these components, i.e. the light-harvesting properties of the perovskite material and the back electrode function of the conductive particles, are applied to the optoelectronic device in one single deposition step, as opposed to a series of subsequent depositions.

Deposition of a perovskite composition comprising perovskite precursors, carbon constituents as well as the matrix polymer together provides three functions in one step: (I) the formation of the carbon back electrode, (ii) the formation of the perovskite crystal upon drying of the perovskite composition, and (iii) the passivation and/or encapsulation of the perovskite/inorganic material by the matrix polymer.

Alternatively, the conductive particles may be comprised in a separate electrode composition disposed as a separate electrode layer on the optoelectronic device. If the conductive particles are disposed as part of a separate composition, this composition will be applied after the perovskite layer has been disposed onto the device. Preferably, the electrode layer will be applied last and may optionally be followed only by an encapsulant glue, or an encapsulant film, which may for example be a transparent or translucent or opaque plastic film or a suitable composite film, and/or by a covering plate.

Different from the perovskite precursor material and the matrix polymer, the conductive particles do not diffuse into the underlying layers during the fabrication of the layered optoelectronic device. The conductive particles are therefore contained in a layer, which functions as the back electrode. The conductive particles are contained in this layer regardless of whether they are disposed onto the device as part of the perovskite composition or as part of a separate electrode composition.

In a preferred embodiment, the perovskite composition can be inkjet printed, slot die coated, screen-printed, or blade coated. To facilitate inkjet printing of the composition, suitable organic solvents may be chosen. The solvents are ideally complemented with a wetting agent, or surfactant. The function of the wetting agent is to disperse any particles in the composition and to prevent aggregation as well as form homogeneous films upon deposition. Aggregation of particles, such as carbon particles, in the composition may cause clogging of inkjet nozzles or other narrow or small opening through which the composition passes during the deposition step and should therefore be avoided.

The perovskite composition may however also be applied onto the device by other methods, such as, without limitation, by screen printing, slot die coating, spin coating, gravure printing, flexo-printing, aerosol jet, spray coating, blade coating.

The composition may furthermore comprise a binding agent and/or other additives. The addition of a binding agent results in a better spatial delimitation of the layered composition. Suitable binding agents are commonly known. Preferably, the binding agent is burned out as part of the annealing step. This means that the binding agent is not comprised in the annealed layer. A suitable binding agent is for example ethyl cellulose or a cellulose derivative.

The mobilisation of the individual components of individual layers, can give rise to distinct zones in which particular components concentrate. This is for example the case for the carbon constituent for the perovskite layer, which, if contained in the perovskite composition, accumulates in the first layer. In contrast, as part during annealing of this first layer, the perovskite material as well as the matrix polymer contained in the perovskite composition diffuses over the other merged functional layers of the device. As a result, the perovskite material forms crystals in the merged functional layers and is not confined to the original layer as disposed.

The invention furthermore discloses an optoelectronic device comprising the described perovskite composition. The optoelectronic device further comprises layers made of a second composition, a third composition and, optionally, if the perovskite composition does not comprise conductive particles, an electrode layer made of an electrode composition comprising conductive particles. The second composition gives rise to a second layer and the third composition gives rise to a third layer.

The second composition includes at least one metal oxide insulating material, such as ZrO₂, preferably mesoporous ZrO₂, Al₂O₃ and/or SiO₂.

Preferably, the second composition furthermore comprise a p-type semiconductor, such as a Nickel-oxide (“NiOx”), CuO, and/or CuSCN. The p-type semi-conductor acts as hole-transport material. It enhances the conductivity resulting in a faster transformation of energy of the optoelectronic device. Conventionally, the metal oxide insulating material and the p-type semiconductor are disposed in separate layers. Combining the two components in one composition enhances the efficacy in the production of the optoelectronic device, as the number of fabrication steps is reduced, and energy as well as cost is saved due to omitting the additional separate disposition and annealing steps, which are required for fabricating two separate functional layers.

It is however also possible to provide the p-type semiconductor in a separate composition in the fabrication of the optoelectronic device. The p-type semiconductor may be disposed in a separate layer.

The third composition contains at least one metal oxide semiconductor, preferably a colourless semiconductor, such as TiO₂, preferably having a band gap equal to or greater than 2.7 eV, or equal to or greater than 3 eV.

The third composition may comprise mesoporous TiO₂ as well as compact TiO₂. The provision of both, mesoporous as well as compact TiO₂ in the same composition enhances the efficiency in the fabrication of the optoelectronic device, as only one deposition and only one annealing step are required to dispose both TiO₂ structures onto the device. Habitually the different forms are disposed in separate layers, necessitating at least two deposition and annealing steps. Combining the two different structures of TiO₂ in the one composition therefore also reduces cost and enhances energy-efficiency in the fabrication of the optoelectronic device.

Similar to the perovskite composition, the second and the third composition preferably comprise suitable organic solvents, which may be complemented by surfactants, binding agents, stabilizing agent like ethanol amine, which stabilizes the compact Titania precursor and prevent fast oxidation and/or other additives.

An advantage of combining mesoporous and the compact TIO₂ in one composition is that the thickness of the TiO₂ layer can be increased, this enhancing the performance of the optoelectronic device. Preferably the thickness of the TiO₂ layer ranges from 50 nanometre to 1500 nanometre, or of 300 nanometre to 800 nanometre, preferably of 450 nanometre to 550 nanometre.

However, mesoporous TiO₂ and compact TiO₂ may also be disposed separately on the optoelectronic device in consecutive steps, such as to form distinct layers.

Either of the two compositions is suited to be used in perovskite-based optoelectronic devices having layers, compositions and/or an architecture, which differ from the device and the different examples described herein.

The functional layers of the optoelectronic device, comprising the layers produced by the perovskite composition, the second composition, the third composition, and the optional electrode composition are preferably superposed on a suitably prepared substrate. The substrate may for example be glass coated with fluorine doped tin oxide (FTO). Laser ablation may be used to scribe the FTO coating on the substrate. Alternatively, the substrate may be a plastic, such as polymethyl methacrylate, also called perspex. The substrate may also be a metal like steel or a metal oxide. However, the invention is not limited to these examples and other suitable substrates, for example metals or metal-oxide semiconductors, such as ZnO, TiO₂, SnO₂, Al-doped ZnO (AZO), NiOx, vanadium oxide, SiO₂, Al₂O₃ Si, graphene, as well other 2D transition metal chalcogenides, such as MoS₂, MeSe₂, FeS₂, and VS₂, may be chosen.

Remarkably, the perovskite composition, as well as the second, the third composition and the optional electrode composition may all be printed onto the device in superposed layers as part of an inkjet printing process. This deposition method is particularly advantageous, if a high precision of layer deposition is desired. In addition, it is highly customizable to the different shapes of the devices, respectively the desired patterns in which the functional layers should be disposed. Furthermore, compared to other deposition procedures inkjet printing is extremely fast, which again renders it perfectly suited for the production of small to large scale optoelectronic devices.

In addition, inkjet printing is readily adaptable to any desired shape, i.e. it is not bound to any particular shape and is therefore form-free. It can be used in combination with laser scribing for interconnects (P1, P2, P3). Alternatively, it can be set to print ink compositions only on areas on which they are required and therefore eliminating the P2 and P3 laser scribing steps.

Deposition by means of inkjet printing is fast and extremely versatile and therefore suited for a wide range of optoelectronic devices. The ability to use inkjet printing for deposition of all functional layers of the device is a distinct advantage in terms of application range, efficacy as well as cost and energy efficiency.

The optoelectronic device may furthermore comprise an encapsulant layer or film, which is disposed on top or the layered functional compositions. The device may also comprise a transparent or translucent cover plate. The purpose of the encapsulant layer and/or the cover plate is to protect the functional layers of the device from environmental influences. The encapsulant layer and/or cover plate protect the functional layer from mechanical or chemical damage due to external factors. The encapsulant, if in form of liquid adhesive or a glue, can further be coated or inkjet printed.

Preferably, the functional layers of the optoelectronic device are superposed, such that the third layer is closest to the substrate and that the second layer is positioned between the third layer and the first layer. The electrode layer is positioned on top of the layered device, facing the light. The layers may be sandwiched between the substrate and the encapsulant film or layer, respectively the cover plate.

The invention furthermore concerns a method for producing the optoelectronic device described here above, comprising the steps of disposing a layer of the third composition comprising at least one metal oxide semiconductor, preferably a colourless semiconductor, such as TiO₂, preferably having a band gap equal to or greater than 2.7 eV, or equal to or greater than 3 eV on a suitable substrate to form a third layer, disposing the second composition comprising at least one metal oxide insulating material, such as ZrO₂, preferably mesoporous ZrO₂, Al₂O₃ and/or SiO₂ on the annealed third layer to form a second layer, disposing of the perovskite composition comprising an organic precursor of a metal-halide perovskite, an inorganic material, a matrix polymer, and, optionally, conductive particles on the annealed second layer to form a first layer, and, optionally, disposing of an electrode composition comprising conductive particles on the annealed first layer, and annealing the disposed insulator composition.

Each layer may either be annealed individually following its deposition or co-annealed with at least one other layer in one annealing step.

Annealing of the second and/or the third layer may be performed under ambient conditions at temperatures at or below 135 degrees Celsius, or at high temperatures, at or above 300 degrees Celsius. Annealing of the first layer however must be performed at temperatures at or below 135 degrees Celsius, preferably below 115 degrees Celsius. Optionally all three functional layers, i.e. the first layer, the second layer and the third layer are each annealed at temperatures at or below 135 degrees Celsius, preferably ranging from 30 degrees Celsius to 100 degrees Celsius, or from 60 degrees Celsius to 90 degrees Celsius.

Each layer may be dried prior to annealing and/or deposition of a subsequent layer. The drying step serves to partially of fully remove solvents of the compositions from the drying layer. The individual disposed layers may each be annealed in a separate annealing step. Alternatively, superposed layers may also be co-annealed or co-fired. Co-firing of the different layer further enhances the production efficiency of the optoelectronic device. It also renders the fabrication method even more efficient in terms of time, cost and energy expenditure.

Binding agents are generally not removed as part of a drying step. Any remaining solvents are preferably removed during the annealing procedure, which also destroys and/or removes the binding agent comprised in the layer.

Remarkably, the perovskite layer, as well as the second and third layers, i.e. the functional layers, can all be deposited by inkjet printing. The inkjet printing step may be realized by using a printing machine suitable for inkjet printing.

It is understood that various embodiments and modifications of the present embodiments and examples described herein will be obvious to those skilled in the art. To the extent that such embodiments and modifications do not depart from the scope of the claims, it is intended that they are also included in the invention disclosed herein.

### SHORT DESCRIPTION OF THE DRAWINGS

Exemplar embodiments of the invention are disclosed in the description and illustrated by the drawings in which:

FIG. 1 illustrates schematically an exemplary embodiment of the order in which individual layers are superposed in the claimed perovskite optoelectronic device; and

FIG. 2 depicts schematically a possible method for producing an exemplary optoelectronic device claimed in the present invention.

### DETAILED DESCRIPTION OF THE PRESENT INVENTION

The invention disclosed herein combines the organic precursor of the metal-halide perovskite material, the inorganic precursor of the perovskite, and a matrix polymer constituent in one single composition. This composition is called the perovskite composition and is used to produce a functional layer, called the first layer, on an optoelectronic device.

The invention furthermore discloses such a preferred optoelectronic device and its configuration. It should however be noted that perovskite composition giving rise to the metal halide-perovskite is suitable for a wide variety of perovskite optoelectronic devices and not necessarily limited to a particular type of device or architecture of the device. Whilst preferred combinations of functional layers are disclosed in this invention, the perovskite composition as described herein may also be used in an optoelectronic device having functional layers of different composition or being produced in a different manner.

The term metal-halide perovskite as used herein refers to an AMX₃ material. A is a cation group, such as methylammonium (MA), butylammonium (BA), formamidinium (FA), phenethylammonium (PEA), Cesium (Cs) or a mixture of such cation groups. M is a metal, such as Sn, Bi, Cu, Ag, preferably Pb, or a mixture of such metals. X is a halide or a combination of halides, such as Cl, Br, or, preferably, I. The absorption spectra of the metal-halide perovskite can be fine-tuned due to the nature of the halide component, respectively the ratio of the halides contained in the perovskite material. In a preferred embodiment the metal-halide perovskite is a lead halide perovskite. However, the invention is not limited to this example.

The organic precursor of the metal-halide perovskite is an organic halide, consisting of an organic cation and a halide anion. The inorganic material of the claimed composition preferably comprises a suitable metal-halide salt.

Halide anions for organic or metal salts may be selected from a group consisting of fluoride (F⁻), chloride (Cl⁻), bromide (Br⁻), iodide (I⁻).

In a one embodiment the organic precursor may be MAI and the inorganic material may comprise PbI₂. The combination of organic precursors and metal-halides used in the present invention is not particularly limited and it is obvious to the skilled person, that different combinations may be used.

The claimed perovskite composition furthermore comprises a matrix polymer, such as for example polystyrene (PS), polyethylene terephthalate (PET), polyolefin (PO), poly(vinyl alcohol) (PVA), or, preferably, poly(methyl methacrylate) (PMMA). Preferably, the matrix polymer is provided in the perovskite composition ranges from 0.1 wt % to 50 wt %, preferably from 1 wt % to 10 wt %.

While the matrix polymer is comprised in the perovskite composition in the claimed invention, it is also possible that the matrix polymer is provided in a separate composition. Moreover, a separate matrix polymer composition may also be layered onto the device in addition to the claimed perovskite composition.

A suitable separate matrix polymer composition may for example comprise matrix polymer material ranging from 0.1 wt % to 50 wt %, preferably from 2 wt % to 15 wt % in one or more organic solvents.

A suitable mixture of organic solvents for a separate matrix polymer, such as a PMMA composition may for example primarily comprise terpineol and/or ethyl acetate. During the annealing step, the perovskite layer 1 is merged with its underlying layers 2 and 3. As a result, the organic-metal halide perovskite material diffuses into said underlying layers, such that it is substantially spread over the entire thickness of the merged functional layers 1, 2, 3.

In order to achieve this spreading over the superposed functional layers, the perovskite layer needs to be disposed after the other layers have been formed. This allows the matrix polymer as well as the perovskite material to penetrate the underlying layers. The perovskite material gives rise to a crystals, which as a result of this diffusion span the functional layers 1, 2, 3.

The components of the claimed perovskite composition are provided in an organic solvent or a mixture of organic solvents. The solvents may be protic or aprotic, aromatic or non-aromatic, such as aliphatic alcohols, preferably C1 to C5 aliphatic alcohols, alicyclic alcohols, such as cyclohexanol or cyclopentanol, and other organic solvents such as terpene solvents, including monoterpene alcohols, tetralin, terpineol, γ-butyrolactone (GBL), N-Methyl-2-pyrrolidone (NMP), dimethyl formamide (DMF), dimethyl sulfoxide (DMSO) and mixtures thereof.

Preferably, the claimed perovskite composition comprising a matrix polymer also contain terpineol, ethyl acetate and/or a mixture of ethyl acetate and terpineol (1:1 vol %) which enhances jetting of the ink and homogeneous layer formation

In a preferred embodiment, conductive particles are comprised in the claimed perovskite composition. Such particles may for example be antimony tin oxide (ATO) constituents, Al₂O₃-doped ZnO (AZO) constituents, or indium tin oxide (ITO) constituents, FTO constituents, or, preferably, carbon constituents. The conductive particles may be microparticles and/or nanoparticles, such as carbon black nanoparticles, nanotubes, or graphite and graphene particles, such as graphite flakes, and/or mixtures thereof.

The conductive particles may be provided in solid form or in form of an ink or a paste, comprising in suitable organic solvents. Such suitable solvents may for example comprise terpineol, xylene, GBL, aliphatic alcohols, such as ethanol, aliphatic acetates, such as ethylacetate or a combination thereof.

The perovskite/carbon composition can comprise from 40 wt % to 98 wt % of carbon. The preferred ration of carbon in the perovskite mixture is 80 wt % to 98 wt %, most preferably 95 wt %.

In one embodiment the organic solvent of the perovskite composition is a mixture including an organic solvent having a high boiling point ranging from 181 degrees Celsius to 350 degrees Celsius, such as GBL, NMP, or Terpineol, and an organic solvent having a boiling point below 181 degrees Celsius and may be selected from a group consisting of C1 to C5 aliphatic alcohol, for example ethanol, or form a group consisting of a C1 to C5 aliphatic acetates, for example ethylacetate.

A suitable solvent mixture may for example comprise terpineol combined with either GBL and ethanol, or with NMP and ethanol.

In another embodiment the organic solvent is Acetonitrile (ACN). The organic solvent may also comprise only high boiling point organic solvents like GBL or NMP. To enhance the solubility of the matrix polymer, terpineol should be contained in the solvent mixture.

In one embodiment, the composition comprises further organic components such as wetting agents, binding agents and/or other additives.

The term wetting agent as used herein means surfactant, which may or may not be volatile. The wetting agent may be added to increase spreading and levelling of the components of the composition, in particular the carbon constituent. The wetting agent makes the composition more homogenous.

The addition of a wetting agent is particularly advantageous if the perovskite composition also comprises conductive particles, such as carbon constituents. The wetting agent disperses the conductive particles, and therefore prevents an aggregation of carbon in the composition.

In addition, the wetting agent facilitates the formation of a homogenous and levelled dried layer. For this reason, the addition of a wetting agent is particularly preferable if the composition is layered onto the optoelectronic by inkjet printing, in which the printing nozzle can easily be blocked.

Suitable wetting agents are known in the art and many are commercially available. Wetting agents may for example be alkanes, amines, fluorosurfactants, silicon-based surfactants, such as siloxanes, or hydrocarbon-based surfactants, or a combination thereof.

Binding agents are substances, which hold or draw other materials of the composition together. Binding agents enhance the cohesion and/or adhesion of the composition, both mechanically and chemically.

Preferably a suitable binding agent should be chosen or designed to disintegrate during the annealing step as part of the fabrication of the opto-electronic device. A suitable binding agent should furthermore be soluble in the organic solvents comprised in the composition to which it is added.

Organic binding agents are widely known, and include bitumens, animal and plat glues, and polymers, such as polysaccharides. Binding agents can be waxes, oils, such as linseed oil, gums and proteins, such as egg white or casein. In a preferred embodiment the binding agent is cellulose or a cellulose derivative, such as ethyl cellulose.

In the example presented herein, the functional layers comprise at least one TiO₂ layer, which is the second layer 2, and an insulant layer, which is the third layer 3.

In a preferred embodiment, the second layer 2 is produced using a second composition containing compact TiO₂ as well as mesoporous TiO₂. The second composition may be prepared by mixing separate compositions of which one contains compact TiO₂ precursor and another one contains mesoporous TIO₂.

A compact TIO₂ composition may for example be prepared with an organic titanate precursor, such as titandiisopropoxid bis(acetylacetonate) dissolved in suitable organic solvents, such as a combination of terpineol, xylene, ethylacetate, acetonitrile. The composition may however also be prepared on the basis of other organic solvents such as isopropanol, ethanol, tetralin, decalin, ethylacetate, and others. Preferably a suitable surfactant, such as a fuorosurfactant, for example zonyl-FS 300, HFE 7500, or a siloxane surfactant is added to the composition. The ink is stabilized by addition of stabilizers like amines, such as ethanol amine.

A mesoporous TiO₂ composition may for example be prepared using Titania oxide nanoparticles, which are contained in a suitable organic solvent, preferably at 1 wt % to 25 wt %. A suitable organic solvent may for example be a combination of terpineol, isopropanol and ethanol, preferably in equal volumes. However, mesoporous TiO₂ may also be prepared in other organic solvents. Preferably, the composition comprises a binder, such as ethyl cellulose, polystyrene or PMMA and, optionally, a surfactant.

The addition of a surfactant, also referred to as wetting agent, is particularly desirable for compositions which are disposed onto the device by inkjet printing.

In a preferred aspect of the described embodiment the second composition is prepared by combining the mesoporous TiO₂ composition and the compact TiO₂ composition described above at a suitable ratio. A suitable ratio may for example be 1 volume of the compact TiO₂ composition and 9 volumes of the mesoporous TIO₂ composition. However, the invention is not limited to this particular ratio and other ratios are possible.

The combined compact/mesoporous TiO₂ composition may also be combined in different ways. Different precursors for compact TiO₂ and for mesoporous TIO₂ are known in the art and may be used. The precursors of the different structures may also be mixed directly into a combined compact/mesoporous TiO₂ composition.

Whilst the different structures of the TiO₂, i.e. the compact and the mesoporous form, may be provided in the same second composition, the structures will largely separate from each other as part of the annealing step and each concentrate in separate zones within the second layer.

However, it is also possible, that the compositions comprising either compact TIO₂ or mesoporous TIO₂ are layered onto the optoelectronic device in separate, subsequent deposition steps, as known in the art.

In a preferred embodiment, the third layer 3 is produced using a third composition comprising mesoporous ZrO₂ doped with compact NIOx and/or mesoporous NiOx.

In one aspect of this embodiment the third composition is prepared by combining a ZrO₂ composition containing mesoporous ZrO₂ with a NiOx composition containing compact NiOx and/or mesoporous NIOx. The third composition may however also be prepared in other ways, for example by mixing suitable precursors for ZrO₂ and NiOx directly in the same composition.

A ZrO₂ composition may for example be a zirconia ink, comprising zirconia nanoparticles ranging from 0.1 wt % to 50 wt %, preferable from 1 wt % to 5 wt %, ideally 3 wt % dissolved in suitable organic solvent, such as for example an equal volume mixture of terpineol, ethanol and xylene. Preferably, the composition furthermore comprises a suitable binder, such as such as ethyl cellulose, polystyrene or PMMA and, optionally, a surfactant.

The third composition may then be prepared by mixing compact and mesoporous NIOx precursor sol-gel, respectively a paste, or NIOx particles with the ZrO₂ composition. NIOx may be added to make up ranging from 0.1 wt % to 20 wt % of the third composition.

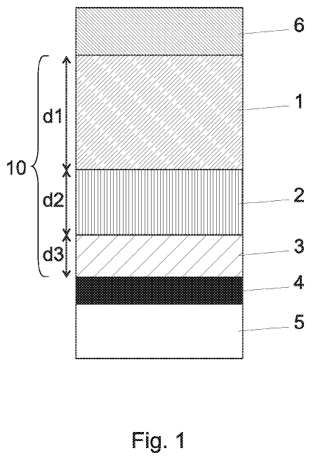

In the embodiment shown in FIG. 1, the functional layers comprise the TiO₂ second layer 2 which contains mesoporous as well as compact TiO₂, and the insulant third layer 3, comprising mesoporous ZrO₂ doped with a mixture of mesoporous and compact NiOx. It should however be noted that the functional layers of the metal halide perovskite optoelectronic device may comprise different suitable compositions and may include further layers comprising individual components of the described functional layers. The number of functional layers is not limited, and neither is the exact order of the layers.

If the metal-halide perovskite is provided in a composition together with conductive particles, such as carbon particles, the perovskite composition 1 is preferably disposed on top of the other functional layers 2, 3. In this embodiment, the metal-halide perovskite diffuses throughout the merged layers 1, 2, 3 in the annealing step, as mentioned above, while the conductive particles substantially concentrate in a layered zone on top of the second 2 and the third 3 functional layers. This zone functions as a back electrode of the optoelectronic device.

The matrix polymer, regardless of whether it is provided with the perovskite composition as part of a separate composition, also diffuses into the merged layers.

FIG. 1 shows a schematic representation of a possible embodiment depicting different layers of an annealed optoelectronic device. Even though the metal-halide perovskite precursors are only contained in the perovskite composition, which is disposed after the third layer 3 and the second layer 2 as claimed herein have been formed on the device, the perovskite material 10 diffuses into the second layer 2 and the third layer 3 once the perovskite layer 1 has been disposed. In the finished device perovskite material 10 is therefore present in the first layer 1, in the second layer 2 and in the third layer 3.

In the embodiment shown in FIG. 1 the conductive particles are not comprised in the perovskite composition. Instead, the conductive particles are disposed as part of a electrode composition forming the electrode layer 6.

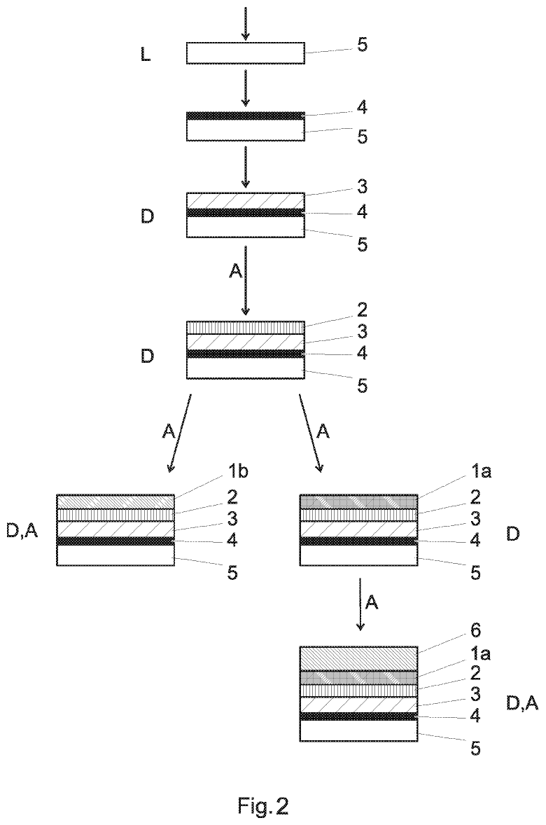

In the example shown in FIGS. 1, which may be prepared using one of the alternative methods shown in FIG. 2, the different ink compositions were disposed onto a substrate 5 coated with FTO 4 in successive order, whereby each layer was annealed on the device after its deposition. Optionally, a disposed layer may be dried before being annealed. It is also possible, that several layers are cofired or co-annealed at the same time.

The third composition comprising a mixture of compact and mesoporous TiO₂, as described above, was used to produce the third layer 3 on the FTO-coated substrate. Preferably, the FTO film is laser scribed L onto the substrate 5. As indicated in FIG. 2 the disposed composition is annealed A prior to a subsequent deposition step D, in which the second composition comprising mesoporous ZrO₂ and mesoporous as well as compact NiOx is layered onto the device and annealed to give rise to the second layer 2. As schematically shown in FIG. 1, typically, the compact and mesoporous TIO₂ layer 3 has a thickness d3 of 50 nanometre to 1500 nanometre, for example between 540 nanometre and 560 nanometre. The second layer generally has a thickness d2 ranging from 50 nanometre to 5000 nanometre, for example from 1450 nanometre to 1550 nanometre. The first layer has preferably has a thickness d1 ranging from 5 micrometre to 25 micrometre.

The third layer 3 of the example described herein can be annealed at high temperatures, for example upon exposure to 500±5 degrees Celsius for 1 hour. Alternatively, the third layer 3 can be annealed at ambient condition, for example at 70±5 degrees Celsius for 10 minutes.

The second layer 2 of the example described herein may be annealed at high temperatures, for example upon exposure to 400±5 degrees Celsius for 1 hour. The second layer 2 can however also be annealed at ambient condition, for example at 90±5 degrees Celsius for 10 minutes.

Once the third layer 3 and the second layer 2 as described herein of the device have been formed, the perovskite composition can be applied. It should be noted that the composition of the second and the third layers are not limited by the example shown in FIG. 1. The second and the third compositions forming said layers may comprise different components or structures of components. The second composition and the third composition used in the process of fabricating the layered optoelectronic device are only limited by the claims. The subsequent steps of producing the carbon perovskite layer may therefore be performed on any device comprising the superposed layers of the second and the third composition as claimed.

Different ways to produce the perovskite crystal and the layered conductive constituents on the optoelectronic device are possible.

In a preferred embodiment a perovskite composition comprising the organic perovskite precursor, the inorganic material, the matrix polymer as well as the conductive particles is layered onto the second layer 2 and annealed A at ambient temperatures, for example at a temperature ranging from 30 degrees Celsius to 135 degrees Celsius, preferably 70±5 degrees Celsius for 10 minutes±3 minutes. Resulting from this, the first layer 1b is formed, which comprises the conductive particles, perovskite material and the matrix polymer, wherein the perovskite material and the matrix polymer diffuse into layers 2 and 3 during the annealing step.

In an optional subsequent step, a matrix polymer composition, for example a PMMA composition, may be disposed D onto this first layer 1b (not shown). The PMMA composition will at least partially penetrate the underlying layers, providing a protective coating of the material, in particular the perovskite crystal formed in these layers. A part of the insulant composition may solidify in form of a protective insulant layer 6 on top of the device.

The deposition of a matrix polymer composition onto a perovskite optoelectronic device is also advantageous for the fabrication of devices which do not comprise a composition, which gives rise to a functional layer and includes a matrix polymer.

In a further preferred embodiment, the perovskite composition does not contain the conductive particles for the back electrode. The perovskite composition is disposed D and annealed A on the device in this perovskite composition to form the first layer 1a. In this embodiment the conductive particles are disposed onto the perovskite layer in a separate deposition step D to form the electrode layer 6. The perovskite layer 1a may be annealed prior deposition of the electrode composition. Alternatively, the electrode deposition may also be disposed on the unannealed perovskite layer 1a. The annealing A conditions for the perovskite layer 1a are the same as for the previous example.

In a further possible example, which is not shown, the a composition comprising the metal halide perovskite precursor and the conductive particles is disposed onto the layers 2 and 3. The composition comprising the metal halide perovskite precursor and the conductive particles, but not the organic precursor, can be annealed on the device at high temperatures, for example at 200-400 degrees Celsius for 1 hour+−30 min, or at ambient temperatures, for example at 90±5 degrees Celsius for 10 minutes±3 minutes.

In a subsequent step of this possible example, a perovskite composition containing the organic perovskite precursor and, optionally, also a metal-halide perovskite salt, may be layered onto the electrode layer and annealed at ambient temperatures, preferably at a temperature ranging from 30 degrees Celsius to 130 degrees Celsius, preferably 70±5 degrees Celsius for 10 minutes±3 minutes. The perovskite material comprised in the resulting layer will diffuse into the underlying functional layers, specifically into the carbon layer, the second layer 2, and the third layer 3 during the annealing step. Optionally, the organic perovskite precursor composition may also comprise a matrix polymer, such as PMMA.

Preferably, each of the functional layers is disposed on the device by an inkjet printing process. However, depending on the specific composition and physical parameters, deposition equipment available and/or requirements of the device, such as its size, different deposition methods may be chosen for each individual layer.

Optionally, the optoelectronic device may be sealed with a transparent or translucent encapsulant layer or film (not shown in the depicted example). The encapsulant serves to protect the functional layers from adverse environmental conditions and influences.

In addition, a transparent or translucent cover plate may be positioned on the layers of the device.

1. A perovskite composition for a functional layer of an optoelectronic device, comprising
an organic precursor of a metal-halide perovskite
an inorganic material,
a polymer matrix material, and
at least one organic solvent,
wherein the perovskite composition is suitable for fabricating said functional layer of an optoelectronic device by annealing at or below 135 degrees Celsius, or below 115 degrees Celsius, preferably at temperatures ranging from 50 degrees Celsius to 80 degrees Celsius.

2. The perovskite composition according to claim 1, wherein the matrix-polymer material comprises one or more polymers selected from a group of polystyrene (PS), polyethylene terephthalate (PET), polyolefin (PO), poly(vinyl alcohol) (PVA), or, preferably, poly(methyl methacrylate) (PMMA), wherein said the content of said matrix polymer comprised in the perovskite composition preferably ranges from 0.1 wt % to 50 wt %.

3. The perovskite composition according to claim 1, wherein the organic precursor is an organic halide salt, such as a methylammonium halide, a formamidinium halide, a butylammonium halide, a guanidinium halide, or a phenethylammonium halide, preferable methylammonium iodide (MAI).

4. The perovskite composition according to claim 1, wherein the inorganic material is a metal-halide, for example tin halide or a lead halide, preferably lead iodide (PbI₂).

5. The perovskite composition according to claim 1, furthermore comprising conductive particles suitable to function as electrode material, such as, for example, carbon constituents, antimony tin oxide (ATO) constituents, A-doped ZnO (AZO) constituents, or indium tin oxide (ITO), preferably at ranging from 40 wt % to 98 wt %, most preferably 95 wt %.

6. The perovskite composition according to claim 1, wherein the at least one organic solvent, is
Acetonitrile (ACN) and/or a high boiling point solvent having a boiling point from 181° Celcius to 350 Celsius, such as γ-Butyrolactone (GBL), N-Methyl-2-pyrrolidone (NMP), or Terpineol, or
a mixture of ACN or a high boiling point solvent and an organic solvent having a boiling point below 181 degrees Celsius, which may be an aliphatic alcohol, an aliphatic acetate and/or xylene.

7. The perovskite composition according to claim 1, wherein the composition is adapted for inkjet printing.

8. An optoelectronic device containing the perovskite composition according to claim 1 applied as a first layer, further comprising the following layers:
a second layer made of a second composition comprising at least one metal oxide insulating material, such as ZrO₂, preferably mesoporous ZrO₂, Al₂O₃ and/or SiO₂, and
a third layer made of a third composition comprising at least one metal oxide semiconductor, preferably a colourless semiconductor, such as TiO₂, preferably having a band gap equal to or greater than 2.7 eV, or equal to or greater than 3 eV, and
optionally, if the perovskite composition does not comprise a conductive particle, an electrode layer made of an electrode composition comprising conductive particles.

9. An optoelectronic device according to claim 8, wherein the second composition furthermore comprises a p-type semiconductor such as a Nickel oxide, preferably NiO or NiO₂.

10. An optoelectronic device according to claim 8, wherein the third composition comprises mesoporous as well as compact TiO₂, preferably at a ratio of 9:1 vol %.

11. An optoelectronic device according to claim 8, wherein the perovskite composition, the second composition, the third composition and the optional electrode composition are suitable for inkjet printing.

12. An optoelectronic device according to claim 8, furthermore comprising a substrate, which is preferably coated with a conductive layer, such as fluorine doped tin oxide (FTO), and, optionally, an encapsulant layer, for example comprising an encapsulant glue, disposed on the light-harvesting surface of the opto-electronic device.

13. An optoelectronic device according to claim 8, wherein the device comprises a substrate, on which a first layer made of the perovskite composition, a second layer made of the second composition, a third layer made of the third composition and, optionally, an electrode layer made of the electrode composition are at least partially disposed, such that the third layer is closest to the substrate, that the second layer is positioned between the third layer and the first layer and that the optional electrode layer is positioned on top layered assembly.

14. An optoelectronic device according to claim 8, wherein the perovskite composition is spread over at least the second layer and the third layer.

15. A method for producing the optoelectronic device of claim 8 comprising the steps of:
a. Disposing a layer of the third composition comprising at least one metal oxide semiconductor, preferably a colourless semiconductor, such as TiO₂, preferably having a band gap equal to or greater than 2.7 eV, or equal to or greater than 3 eV on a suitable substrate to form a third layer,
b. Disposing the second composition comprising at least one metal oxide insulating material, such as ZrO₂, preferably mesoporous ZrO₂, Al₂O₃ and/or SiO₂ on the annealed third layer to form a second layer,
c. Disposing of the perovskite composition comprising an organic precursor of a metal-halide perovskite, an inorganic material, a matrix polymer, and, optionally, conductive particles on the annealed second layer to form a first layer,
d. Optionally, disposing of an electrode composition comprising conductive particles on the annealed first layer, and annealing the disposed insulator composition,
wherein each layer is either annealed individually following its deposition or wherein at least two layers are co-annealed in an annealing step.

16. The method for producing the optoelectronic device according to claim 15, wherein annealing of at least the first layer is performed at temperatures at or below 115 degrees Celsius, preferably ranging from 30 degrees Celsius and 100 degrees Celsius, more preferably ranging from 60 degrees Celsius to 90 degrees Celsius for a period of less than 60 minutes, or of less than 15 minutes, preferably for a period of 8 minutes to 12 minutes.

17. The method for producing the optoelectronic device according to claim 15, wherein the perovskite composition, the second composition and/or the third composition are inkjet printed.
